(19) United States
(12) Patent Application Publication
(10) Pub. No.: US 2025/0008747 A1
(43) Pub. Date: Jan. 2, 2025

(54) THREE-DIMENSIONAL MEMORY DEVICE AND METHOD OF MANUFACTURING THE SAME

(71) Applicant: Samsung Electronics Co., Ltd., Suwon-si (KR)

(72) Inventors: Suhyun Bang, Suwon-si (KR); Seulji Song, Suwon-si (KR); Youngsun Song, Suwon-si (KR)

(21) Appl. No.: 18/537,013

(22) Filed: Dec. 12, 2023

(30) Foreign Application Priority Data
Jun. 30, 2023 (KR) 10-2023-0085118

(51) Int. Cl. H10B 63/00; G11C 5/06; H10N 70/00

(52) U.S. Cl. CPC H10B 63/84; G11C 5/063; H10N 70/8825; H10N 70/8828

(57) ABSTRACT

A three-dimensional memory device includes a base insulating layer on a substrate, a stack structure including word lines and first interlayer insulating layers which are alternately stacked on the base insulating layer, and a second interlayer insulating layer on an uppermost one of the word lines, bit lines that are in the stack structure and spaced apart from each other in a first direction parallel to a top surface of the substrate, each bit line including a first portion that protrudes from a top surface of the stack structure and a second portion that are in the stack structure, an outer electrode on the stack structure and on the first portions of the bit lines, and a dielectric layer between the outer electrode and the first portion of the bit line and surrounding a side surface of the first portion of the bit line in plan view.

### CROSS-REFERENCE TO RELATED APPLICATIONS

This U.S. non-provisional patent application claims priority under 35 U.S.C. § 119 to Korean Patent Application No. 10-2023-0085118, filed on Jun. 30, 2023, in the Korean Intellectual Property Office, the entire contents of which are hereby incorporated by reference.

### BACKGROUND

The present disclosure relates to a three-dimensional memory device and a method of manufacturing the same.

A typical resistive memory device (e.g., a RRAM device, a PRAM device, or a MRAM device) may include a memory material of storing a resistance state and a separate switch (e.g., a transistor, a diode, a threshold switch, etc.). On the contrary, an OTS-only memory device (e.g., a selector only memory device) may include a chalcogenide-based single material showing both memory and selector properties and may have a simple structure including upper and lower electrodes and a SOM material between the upper and lower electrodes, thereby improving an integration density. However, a leakage current of a two-dimensional cell array structure may be increased as a cell array size is increased, and thus a three-dimensional vertical cross-point memory structure has been suggested.

### SUMMARY

Embodiments of the inventive concepts may provide a three-dimensional memory device capable of reducing imbalance of a parasitic capacitance between a word line and a bit line to improve reliability.

Embodiments of the inventive concepts may also provide a method of manufacturing the three-dimensional memory device.

In some embodiments, a three-dimensional memory device may include a base insulating layer on a substrate, a stack structure comprising word lines and first interlayer insulating layers which are alternately stacked on the base insulating layer, and a second interlayer insulating layer on an uppermost one of the word lines, bit lines that are in the stack structure and are spaced apart from each other in a first direction parallel to a top surface of the substrate, ones of the bit lines include respective first portions that protrude from a top surface of the stack structure and respective second portions that are in the stack structure, an outer electrode on the stack structure and on the first portions of the ones of the bit lines, and a dielectric layer between the outer electrode and the first portions of the ones of the bit lines and the dielectric layer surrounds a side surfaces of the first portions of ones of the bit lines in plan view. The outer electrode may be spaced apart from the first portions of the ones of the bit lines with the dielectric layer interposed therebetween.

In some embodiments, a three-dimensional memory device may include a base insulating layer on a substrate, an outer electrode on the base insulating layer, a stack structure comprising first interlayer insulating layers and word lines which are alternately stacked on the outer electrode, bit lines that are in the stack structure and the outer electrode and are spaced apart from each other in a first direction parallel to a top surface of the substrate, and a dielectric layer between ones of the bit lines and the outer electrode and on side surfaces of the ones of the bit lines.

In some embodiments, a method of manufacturing a three-dimensional memory device may include forming a base insulating layer on a substrate, alternately stacking word lines and first interlayer insulating layers on the base insulating layer, forming a mold insulating layer on an uppermost one of the word lines, forming bit line holes in the mold insulating layer, the word lines and the first interlayer insulating layers, and extending into an upper portion of the base insulating layer, forming bit lines in the bit line holes, respectively, etching an upper portion of the mold insulating layer to form a second interlayer insulating layer and to expose respective first portions of ones of the bit lines, forming a dielectric layer on a top surface and a side surface of the first portions of the ones of the bit lines and extending onto the second interlayer insulating layer, and forming an outer electrode on the dielectric layer.

In some embodiments, a three-dimensional memory device includes a base insulating layer on a substrate, word lines and interlayer insulating layers which are alternately stacked on the base insulating layer, bit lines that are in the word lines and the interlayer insulating layers, and are spaced apart from each other in a first direction parallel to a top surface of the substrate. The bit lines each includes a first portion that protrudes from a top surface of an uppermost one of the interlayer insulating layers and a second portion that is in the word lines and the interlayer insulating layers. The three-dimensional memory device includes a dielectric layer on side surfaces of the respective first portions of ones of the bit lines, an outer electrode on the dielectric layer, and an upper insulating layer on top surfaces of the bit lines, a top surface of the dielectric layer, and a top surface of the outer electrode.

### BRIEF DESCRIPTION OF THE DRAWINGS

FIG. 1A is a plan view illustrating a three-dimensional memory device according to some embodiments of the inventive concepts.

FIG. 1B is a cross-sectional view corresponding to a line I-I′ of FIG. 1A to illustrate a three-dimensional memory device according to some embodiments of the inventive concepts.

FIGS. 2 to 8 are cross-sectional views illustrating a method of manufacturing the three-dimensional memory device of FIG. 1B according to some embodiments of the inventive concepts.

FIG. 9 is a cross-sectional view illustrating a three-dimensional memory device according to some embodiments of the inventive concepts.

FIGS. 10 to 16 are cross-sectional views illustrating a method of manufacturing the three-dimensional memory device of FIG. 9 according to some embodiments of the inventive concepts.

FIG. 17 is a cross-sectional view illustrating a three-dimensional memory device according to some embodiments of the inventive concepts.

### DETAILED DESCRIPTION

Embodiments of the inventive concepts will now be described more fully with reference to the accompanying drawings.

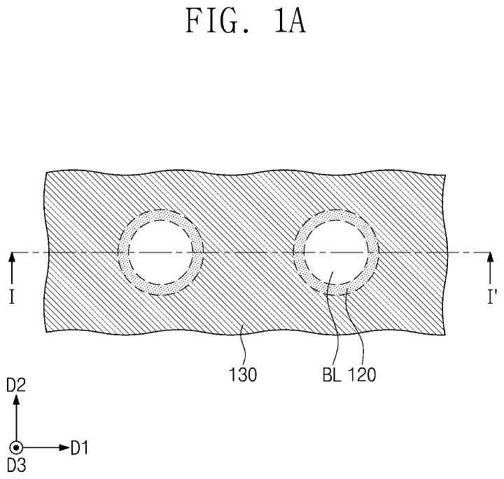

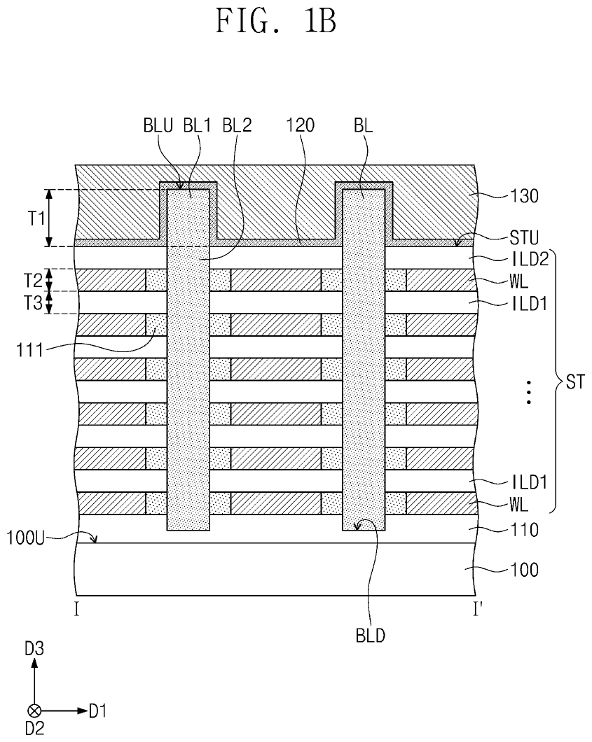

FIG. 1A is a plan view illustrating a three-dimensional memory device according to some embodiments of the inventive concepts. FIG. 1B is a cross-sectional view corresponding to a line I-I′ of FIG. 1A to illustrate a three-dimensional memory device according to some embodiments of the inventive concepts.

Referring to FIGS. 1A and 1B, a substrate 100 may be provided. The substrate 100 may extend in a first direction D1 and a second direction D2 which are parallel to a top surface 100U of the substrate 100 and intersect each other. A third direction D3 perpendicular to the top surface 100U of the substrate 100 may be perpendicular to the first direction D1 and the second direction D2. For example, the first direction D1, the second direction D2 and the third direction D3 may be perpendicular to each other. The substrate 100 may be a semiconductor substrate including silicon (Si), silicon on an insulator (SOI), silicon-germanium (SiGe), germanium (Ge), or gallium-arsenic (GaAs).

A base insulating layer 110 may be provided on the substrate 100. A stack structure ST may be disposed on the base insulating layer 110. The stack structure ST may include word lines WL and first interlayer insulating layers ILD1 alternately stacked on the base insulating layer 110, and a second interlayer insulating layer ILD2 disposed on an uppermost one of the word lines WL.

Each of the base insulating layer 110, the first interlayer insulating layer ILD1 and the second interlayer insulating layer ILD2 may include at least one of silicon oxide, silicon nitride, or silicon oxynitride.

Bit lines BL may be provided to penetrate the stack structure ST. The bit lines BL may be spaced apart from each other in the first direction D1. A bottom surface BLD of each of the bit lines BL may exist in the base insulating layer 110 and may not be in contact with the substrate 100. Each of the bit lines BL may include a first portion BL1 protruding from a top surface STU of the stack structure ST, and a second portion BL2 penetrating the stack structure ST. A first thickness T1 of the first portion BL1 of the bit line BL in the third direction D3 may be greater than a second thickness T2 of the word line WL in the third direction D3 and a third thickness T3 of the first interlayer insulating layer ILD1 in the third direction D3. Thus, a parasitic capacitance of the bit line BL, which will be described below, may have a sufficiently great value, and a speed and reliability of the three-dimensional memory device may be improved.

Even though not shown in the drawings, an integrated circuit may be disposed between the substrate 100 and the bit lines BL. In other words, at least one circuit layer may be disposed in the base insulating layer 110, and the bit lines BL may be electrically connected to the circuit layer.

For example, the word lines WL and the bit lines BL may include at least one of a doped semiconductor (e.g., doped silicon, etc.), a metal (e.g., tungsten, copper, aluminum, etc.), a conductive metal nitride (e.g., titanium nitride, tantalum nitride, etc.), or a transition metal (e.g., titanium, tantalum, etc.). In particular, the word lines WL and the bit lines BL may include tungsten (W).

Storage patterns 111 may be disposed between each of the bit lines BL and the word lines WL. The storage patterns 111 may surround a side surface of each of the bit lines BL in plan view and may be spaced apart from each other in the third direction D3. Each of the storage patterns 111 may have a shape surrounding the side surface of each of the bit lines BL when viewed in a plan view. The word lines WL may be connected to the storage patterns 111, respectively.

The storage patterns 111 may include an ovonic threshold switch (OTS) material (i.e., a chalcogenide-based material). For example, the storage patterns 111 may include at least one of selenium (Se), tellurium (Te), arsenic (As), antimony (Sb), carbon (C), germanium (Ge), silicon (Si), or indium (In).

A dielectric layer 120 may be disposed to cover or overlap the first portions BL1 of the bit lines BL and the second interlayer insulating layer ILD2. For example, the dielectric layer 120 may conformally cover or overlap a side surface and a top surface BLU of the first portion BL1 of the bit line BL and may extend onto the top surface STU of the stack structure ST.

The dielectric layer 120 may include a material having a high dielectric constant, i.e., a high-k dielectric material. For example, the dielectric layer 120 may include at least one of HfO, AlO, TiO, ZrO, or TaO.

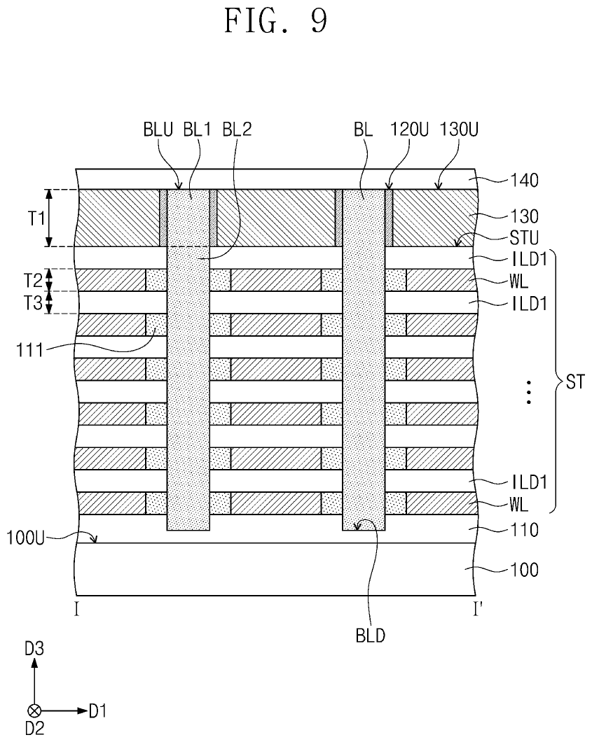

An outer electrode 130 may be disposed on the dielectric layer 120. In other words, the outer electrode 130 may be disposed on the stack structure ST, and the dielectric layer 120 may be disposed between the outer electrode 130 and the stack structure ST. According to the embodiments of the inventive concepts, the dielectric layer 120 may be disposed between the outer electrode 130 and the first portion BL1 of the bit line BL which protrudes from the top surface STU of the stack structure ST, and thus a parasitic capacitor may be formed at an upper portion of the bit line BL. Meanwhile, the word lines WL may have plane shapes to generate a parasitic capacitance between the word lines WL, and thus imbalance (or non-uniformity) of a capacitance between the bit line BL and the word line WL may occur. In this case, a sufficient current may not be generated in a memory programming operation due to the imbalance of the capacitance between the bit line BL and the word line WL, and thus an operating speed and reliability may be reduced. According to the inventive concepts, the capacitance may be generated at the upper portion of the bit line BL to reduce the imbalance of the capacitance between the word line WL and the bit line BL, and thus the operating speed and reliability of the three-dimensional memory device may be improved. In addition, in the case in which the dielectric layer 120 includes the high-k dielectric material described above, the capacitance of the upper portion of the bit line BL may be more improved. Furthermore, the dielectric layer 120 may also be disposed on the top surface BLU of the first portion BL1 of the bit line BL and the outer electrode 130 may be disposed on the dielectric layer 120 as compared with a structure of FIG. 9 to be described below, and thus the capacitance generated at the upper portion of the bit line BL may be increased to minimize the imbalance of the capacitance between the word line WL and the bit line BL.

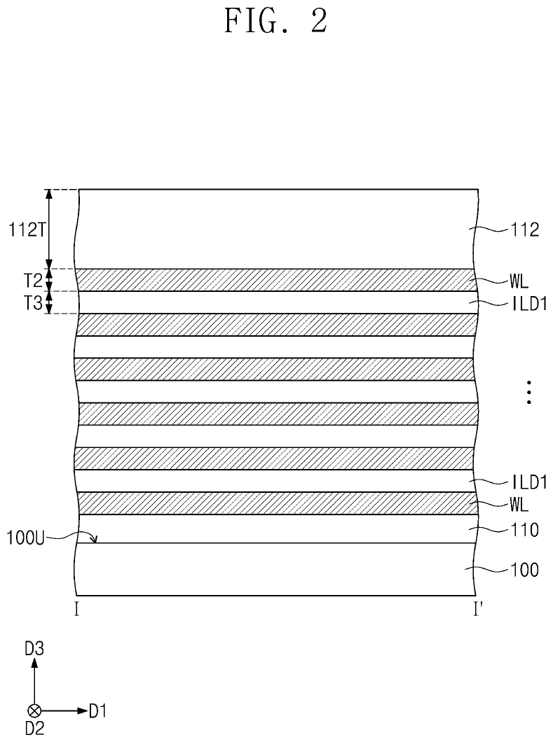

FIGS. 2 to 8 are cross-sectional views illustrating a method of manufacturing the three-dimensional memory device of FIG. 1B according to some embodiments of the inventive concepts.

Referring to FIG. 2, a base insulating layer 110 may be formed on a substrate 100. Word lines WL and first interlayer insulating layers ILD1 may be alternately stacked on the base insulating layer 110. A mold insulating layer 112 may be formed on an uppermost one of the word lines WL. A thickness 112T of the mold insulating layer 112 in the third direction D3 may be greater than a second thickness T2 of the word line WL in the third direction D3 and a third thickness T3 of the first interlayer insulating layer ILD1 in the third direction D3.

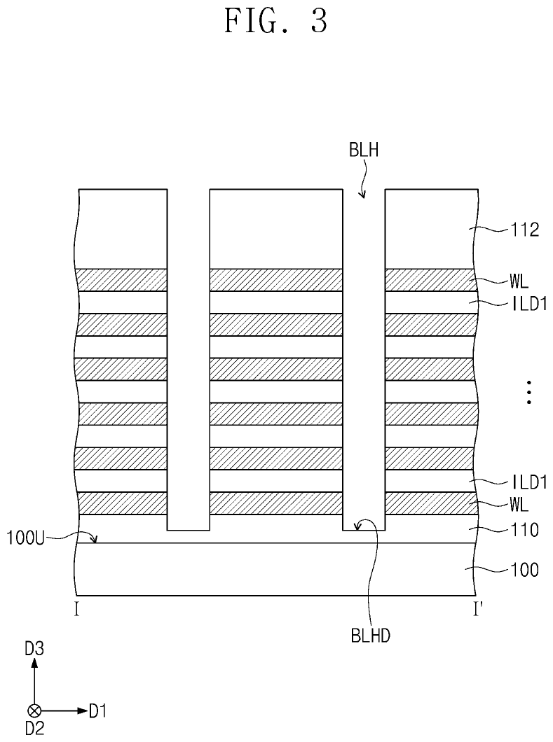

Referring to FIG. 3, bit line holes BLH may be formed to penetrate the mold insulating layer 112, the word lines WL and the first interlayer insulating layers ILD1. The bit line holes BLH may be spaced apart from each other in the first direction DI. A bottom surface BLHD of each of the bit line holes BLH may be located in the base insulating layer 110. In other words, the bit line holes BLH may penetrate an upper portion of the base insulating layer 110 and may not expose the top surface 100U of the substrate 100. The formation of the bit line holes BLH may be performed using an anisotropic etching process.

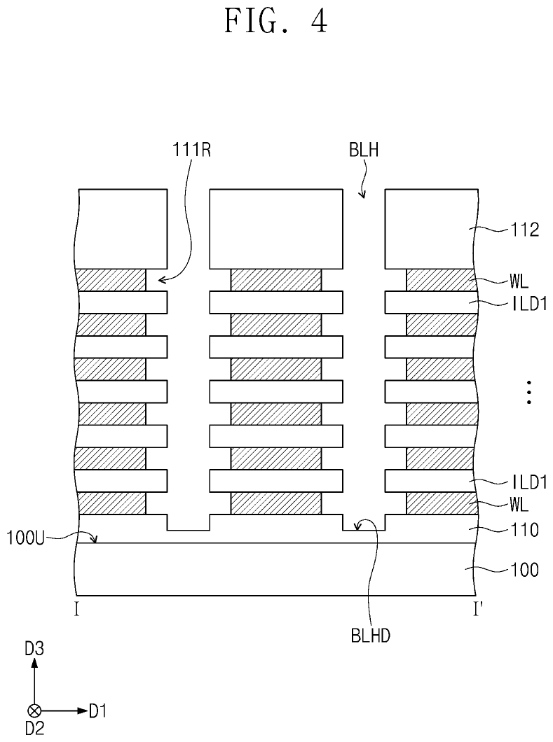

Referring to FIG. 4, side surfaces of the word lines WL exposed by the bit line holes BLH may be etched to form storage pattern recess portions 111R. The process of etching the side surfaces of the word lines WL may be performed by a wet etching process using an etching solution. In the wet etching process, the side surfaces of the word lines WL may be selectively etched, but the base insulating layer 110, the first interlayer insulating layers ILD1 and the mold insulating layer 112 may not be etched.

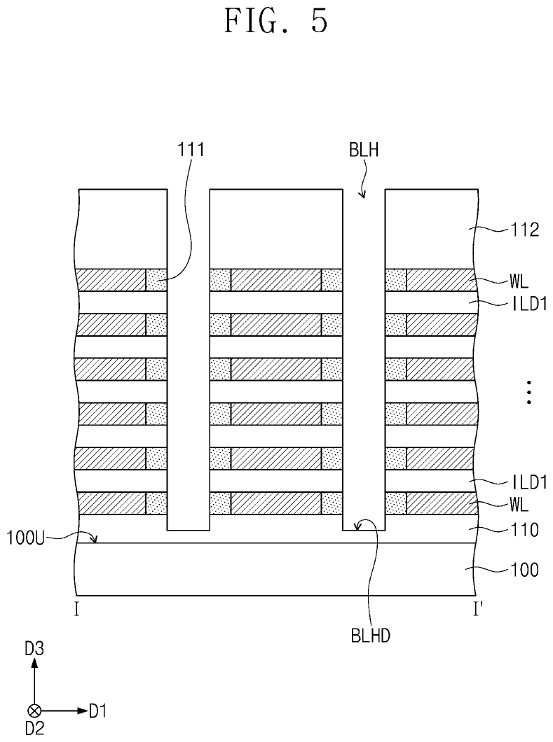

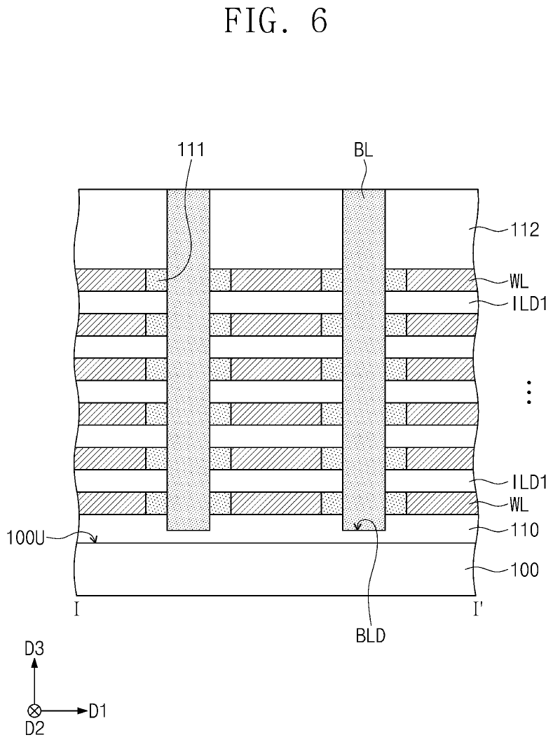

Referring to FIGS. 5 and 6, storage patterns 111 may be formed in each of the storage pattern recess portions 111R. For example, the formation of the storage patterns 111 may include forming a storage layer filling the storage pattern recess portion 111R and a portion of each of the bit line holes BLH, and removing the storage layer from each of the bit line holes BLH. After the formation of the storage patterns 111, bit lines BL may be formed to fill the bit line holes BLH, respectively. A bottom surface BLD of the bit line BL may be located in the base insulating layer 110. In other words, the bit lines BL may penetrate an upper portion of the base insulating layer 110 and may not be in contact with the substrate 100. The formation of the storage patterns 111 and the bit lines BL may be performed using a layer-formation technique such as a chemical vapor deposition (CVD) technique or a physical vapor deposition (PVD) technique. A material for forming the bit lines BL may be deposited, and then, a planarization process may be performed until a top surface of the mold insulating layer 112 is exposed. For example, the planarization process may be performed using a chemical mechanical polishing (CMP) process or an etch-back process.

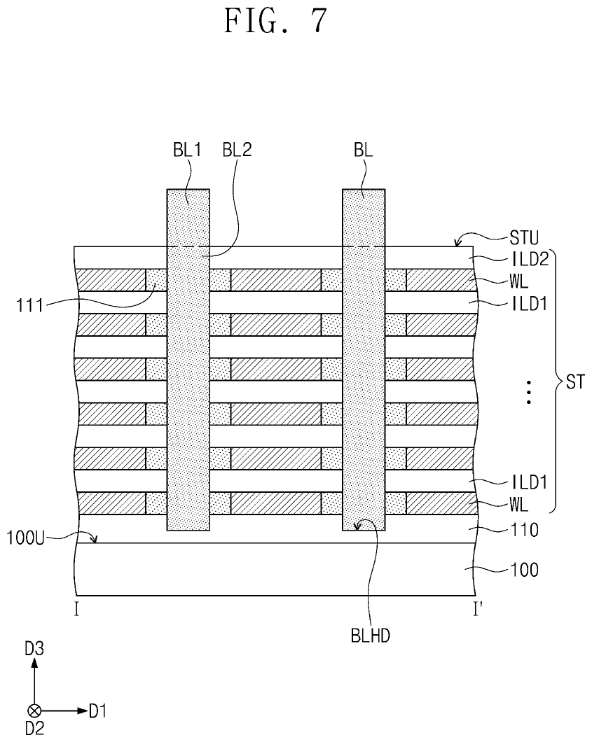

Referring to FIG. 7, an etching process of removing a portion of the mold insulating layer 112 may be performed. A remaining portion of the mold insulating layer 112 after the etching process may be referred to as a second interlayer insulating layer ILD2. In the etching process, the portion of the mold insulating layer 112 may be selectively etched, and upper portions of the bit lines BL may not be etched. The word lines WL, the first interlayer insulating layers ILD1 and the second interlayer insulating layer ILD2 may constitute or be collectively referred to as a stack structure ST. The mold insulating layer 112 may be etched to expose the upper portions of the bit lines BL. Thus, each of the bit lines BL may include a first portion BL1 corresponding to a portion protruding above a top surface STU of the stack structure ST, and a second portion BL2 corresponding to a portion penetrating the stack structure ST.

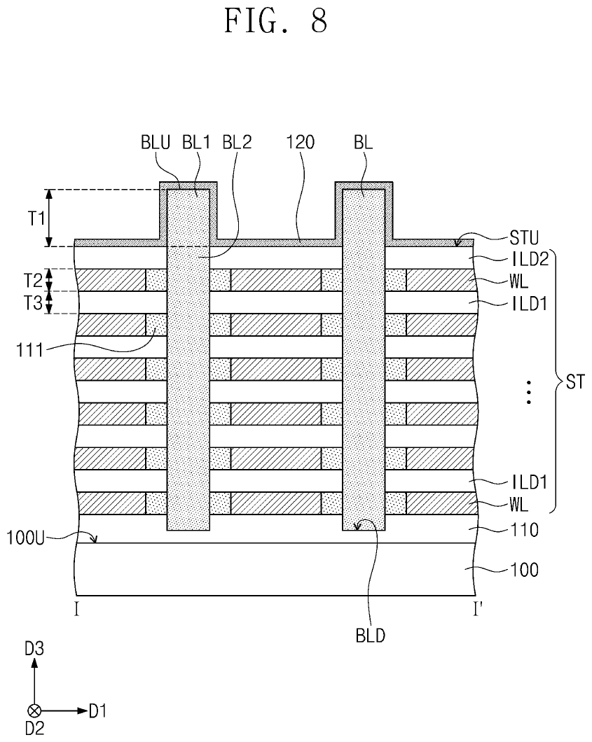

Referring to FIG. 8, a dielectric layer 120 may be formed to cover or overlap a top surface BLU and a side surface of the first portion BL1 of each of the bit lines BL. The dielectric layer 120 may extend onto the top surface STU of the stack structure ST, i.e., a top surface of the second interlayer insulating layer ILD2. The dielectric layer 120 may conformally cover or overlap the top surface BLU and the side surface of the first portion BL1 of the bit line BL. The formation of the dielectric layer 120 may be performed using an atomic layer deposition (ALD) process having excellent step coverage properties. Since the thickness 112T of the mold insulating layer 112 in the third direction D3 is greater than the second thickness T2 of the word line WL in the third direction D3 and the third thickness T3 of the first interlayer insulating layer ILD1 in the third direction D3 as described with reference to FIG. 2, a first thickness Tl of the first portion BL1 of the bit line BL may also be greater than the second thickness T2 of the word line WL in the third direction D3 and the third thickness T3 of the first interlayer insulating layer ILD1 in the third direction D3. Thus, when an outer electrode 130 is formed on the dielectric layer 120 in a subsequent process, a capacitance of a capacitor including the outer electrode 130, the dielectric layer 120 and the first portion BL1 of the bit line BL may be increased. In other words, the capacitance of the capacitor including the outer electrode 130, the dielectric layer 120 and the first portion BL1 of the bit line BL may be adjusted by adjusting the thickness 112T of the mold insulating layer 112 and/or the first thickness T1 of the first portion BL1 of the bit line BL. In addition, the capacitance of the capacitor including the outer electrode 130, the dielectric layer 120 and the first portion BL1 of the bit line BL may be adjusted by adjusting a dielectric constant of the dielectric layer 120. For example, when the dielectric layer 120 includes a material having a relatively high dielectric constant, the capacitance of the capacitor including the outer electrode 130, the dielectric layer 120 and the first portion BL1 of the bit line BL may be increased.

Referring again to FIG. 1B, the outer electrode 130 may be formed on the dielectric layer 120. Thus, a parasitic capacitor may be formed at the upper portion of the bit line BL.

FIG. 9 is a cross-sectional view illustrating a three-dimensional memory device according to some embodiments of the inventive concepts. Hereinafter, differences between the present embodiments and the above embodiments will be mainly described for the purpose of ease and convenience in explanation.

Referring to FIG. 9, a base insulating layer 110 may be provided on a substrate 100, and a stack structure ST including word lines WL and first interlayer insulating layers ILD1 which are alternately stacked may be disposed on the base insulating layer 110. An outer electrode 130 may be disposed on the stack structure ST.

Bit lines BL may be provided to penetrate the outer electrode 130 and the stack structure ST. The bit lines BL may be spaced apart from each other in the first direction D1. Each of the bit lines BL may include a first portion BL1 protruding from a top surface STU of the stack structure ST, and a second portion BL2 penetrating the stack structure ST. A first thickness T1 of the first portion BL1 of the bit line BL in the third direction D3 may be greater than a second thickness T2 of the word line WL in the third direction D3 and a third thickness T3 of the first interlayer insulating layer ILD1 in the third direction D3. Thus, a parasitic capacitance of the bit line BL, which will be described below, may have a sufficiently great value, and an operating speed and reliability of the three-dimensional memory device may be improved.

Dielectric layers 120 may be disposed between the outer electrode 130 and the bit lines BL, respectively, and may surround in plan view side surfaces of the first portions BL1 of the bit lines BL, respectively. Top surfaces 120U of the dielectric layers 120 may be substantially coplanar with top surfaces BLU of the bit lines BL and a top surface 130U of the outer electrode 130.

An upper insulating layer 140 may be disposed on the outer electrode 130. The upper insulating layer 140 may be in contact with the top surface BLU of each of the bit lines BL and the top surface 120U of each of the dielectric layers 120. In other words, the top surfaces BLU of the bit lines BL may not be covered (i.e., not overlap) with the dielectric layers 120. For example, the upper insulating layer 140 may include at least one of silicon oxide, silicon nitride, or silicon oxynitride.

The dielectric layer 120 may be disposed between the outer electrode 130 and the first portion BL1 of the bit line BL to form a capacitor. Imbalance of a capacitance between the bit line BL and the word line WL may be reduced using a capacitance of the capacitor and a parasitic capacitance between the word lines WL, and thus the operating speed and reliability of the three-dimensional memory device may be improved.

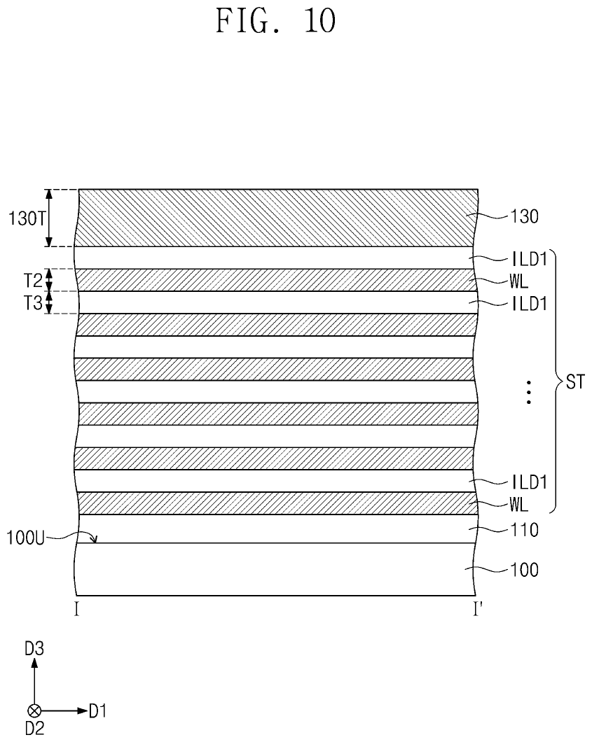

FIGS. 10 to 16 are cross-sectional views illustrating a method of manufacturing the three-dimensional memory device of FIG. 9 according to some embodiments of the inventive concepts.

Referring to FIG. 10, a base insulating layer 110 and a stack structure ST may be sequentially formed on a substrate 100. The stack structure ST may include word lines WL and first interlayer insulating layers ILD1 which are alternately stacked. An outer electrode 130 may be formed on the stack structure ST. A thickness 130T of the outer electrode 130 in the third direction D3 may be greater than a second thickness T2 of the word line WL in the third direction D3 and a third thickness T3 of the first interlayer insulating layer ILD1 in the third direction D3. Thus, a first thickness T1, in the third direction D3, of a first portion BL1 of a bit line BL formed in a subsequent process may be greater than the second thickness T2 of the word line WL in the third direction D3 and the third thickness T3 of the first interlayer insulating layer ILD1 in the third direction D3.

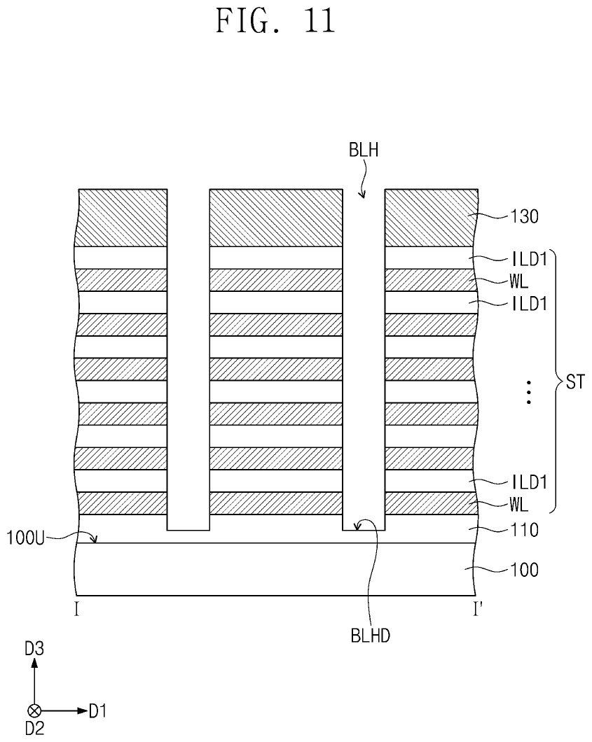

Referring to FIG. 11, bit line holes BLH may be formed to penetrate the outer electrode 130, the first interlayer insulating layers ILD1 and the word lines WL. The bit line holes BLH may be spaced apart from each other in the first direction D1. A bottom surface BLHD of each of the bit line holes BLH may be located in the base insulating layer 110. In other words, the bit line holes BLH may penetrate an upper portion of the base insulating layer 110 and may not expose the top surface 100U of the substrate 100. The formation of the bit line holes BLH may be performed using an anisotropic etching process using an ion beam.

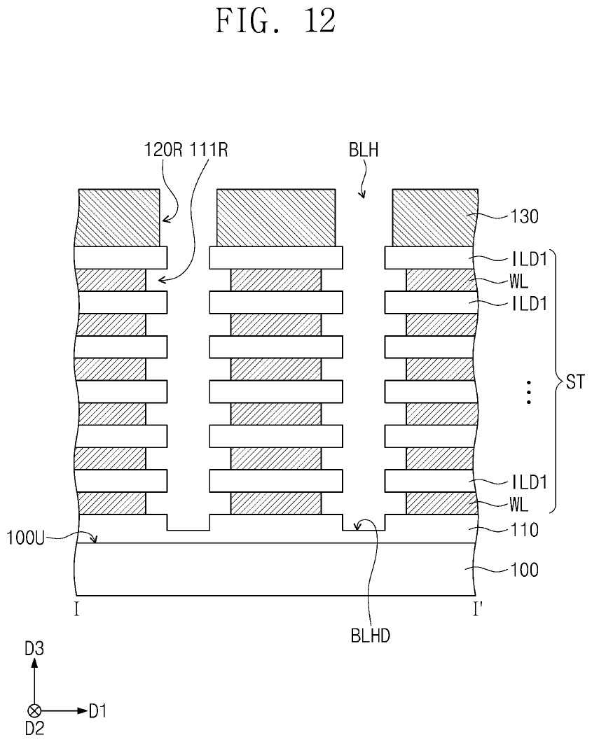

Referring to FIG. 12, portions of the word lines WL and the outer electrode 130 exposed by the bit line holes BLH may be etched to form storage pattern recess portions 111R and dielectric pattern recess portions 120R. The formation of the storage pattern recess portion 111R and the dielectric pattern recess portion 120R may be performed using a wet etching process. In the process of forming the storage pattern recess portion 111R and the dielectric pattern recess portion 120R, side surfaces of the word lines WL and the outer electrode 130 may be selectively etched by the wet etching process, but the first interlayer insulating layers ILD1 and the base insulating layer 110 may not be etched by the wet etching process.

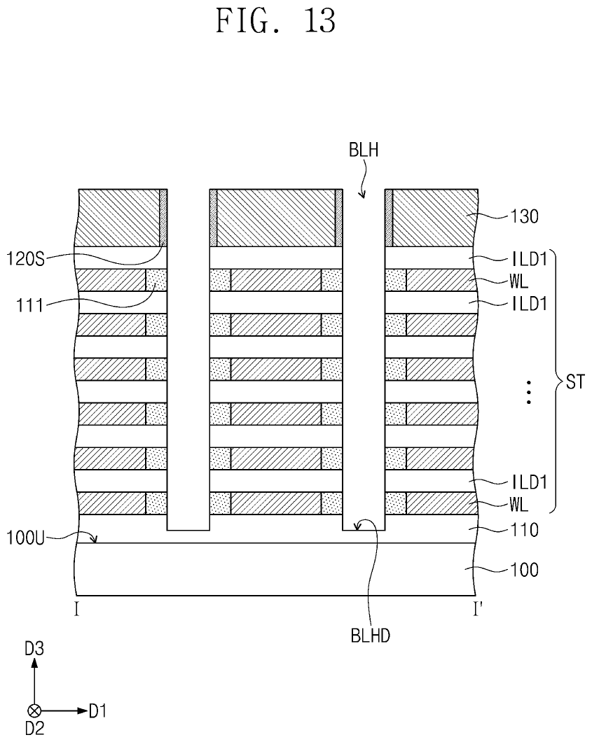

Referring to FIG. 13, storage patterns 111 may be formed in each of the storage pattern recess portions 111R. A dielectric pattern sacrificial layer 120S may be formed in the dielectric pattern recess portion 120R. The dielectric pattern sacrificial layer 120S may be formed of the same material as the storage patterns 111. For example, the formation of the dielectric pattern sacrificial layer 120S and the storage patterns 111 may include forming a storage layer filling the storage pattern recess portion 111R, the dielectric pattern recess portion 120R and a portion of each of the bit line holes BLH, and removing the storage layer from each of the bit line holes BLH.

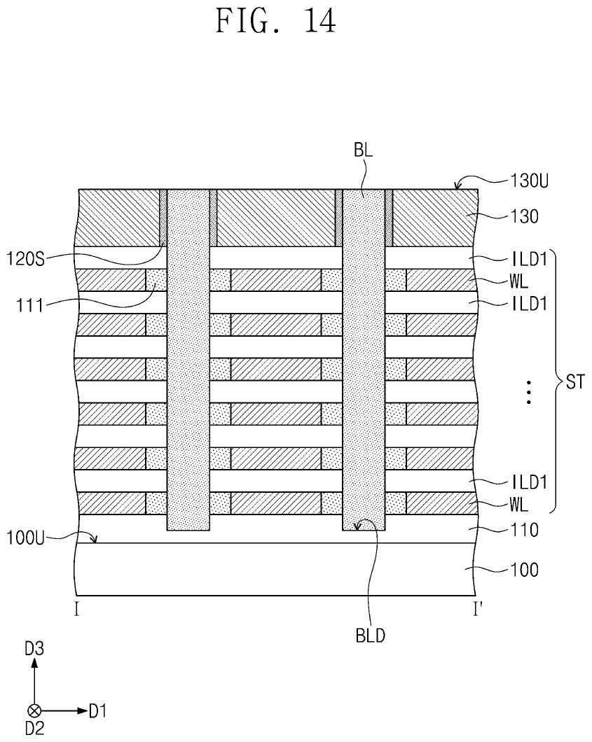

Referring to FIG. 14, bit lines BL may be formed to fill the bit line holes BLH, respectively. A bottom surface BLD of the bit line BL may be located in the base insulating layer 110. In other words, the bit lines BL may penetrate an upper portion of the base insulating layer 110 and may not be in contact with the substrate 100. The formation of the bit lines BL may be performed using a layer-formation technique such as a chemical vapor deposition (CVD) technique or a physical vapor deposition (PVD) technique. A material for forming the bit lines BL may be deposited, and then, a planarization process may be performed until a top surface 130U of the outer electrode 130 is exposed. For example, the planarization process may be performed using a chemical mechanical polishing (CMP) process or an etch-back process. The dielectric pattern sacrificial layer 120S may be exposed by the planarization process.

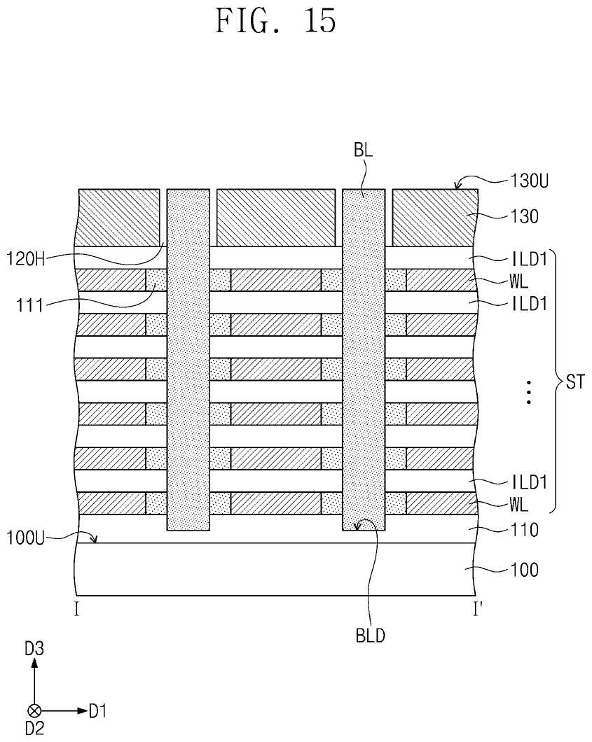

Referring to FIG. 15, the dielectric pattern sacrificial layer 120S may be removed to form a dielectric pattern hole 120H. The formation of the dielectric pattern hole 120H may be performed using a wet etching process. In the wet etching process, the dielectric pattern sacrificial layer 120S may be selectively removed, but the bit lines BL and the outer electrode 130 may not be etched.

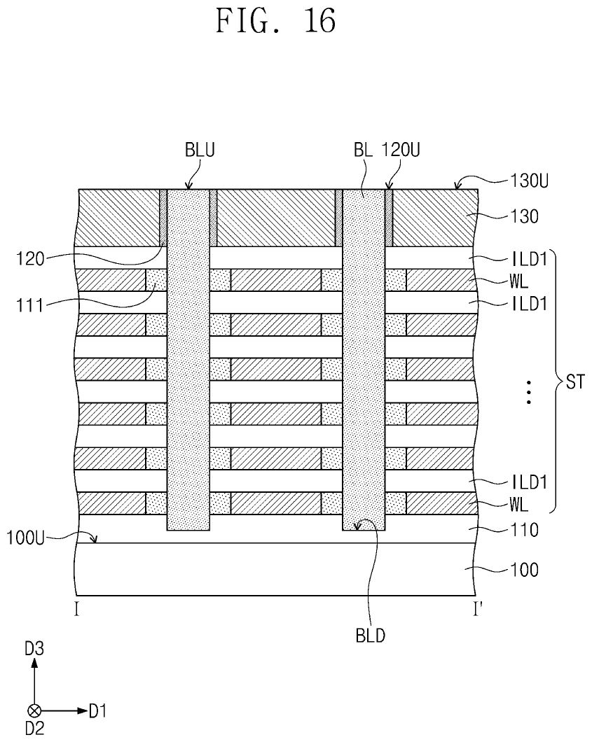

Referring to FIG. 16, a dielectric layer 120 may be formed to fill the dielectric pattern hole 120H. The formation of the dielectric layer 120 may be performed using an atomic layer deposition (ALD) process having excellent step coverage properties. A material for forming the dielectric layer 120 may be deposited, and then, a planarization process may be performed to expose the top surface 130U of the outer electrode 130 and the top surfaces BLU of the bit lines BL. The top surface 130U of the outer electrode 130, the top surfaces BLU of the bit lines BL and top surfaces 120U of the dielectric layers 120 may be substantially coplanar with each other.

Referring again to FIG. 9, an upper insulating layer 140 may be formed on the outer electrode 130. As compared with the manufacturing method described with reference to FIGS. 2 to 8, the process of etching the mold insulating layer 112 may be omitted in the manufacturing method described with reference to FIGS. 10 to 16. In this case, it is possible to prevent a height dispersion of the second interlayer insulating layer ILD2, which may occur by non-uniform etching of the mold insulating layer 112.

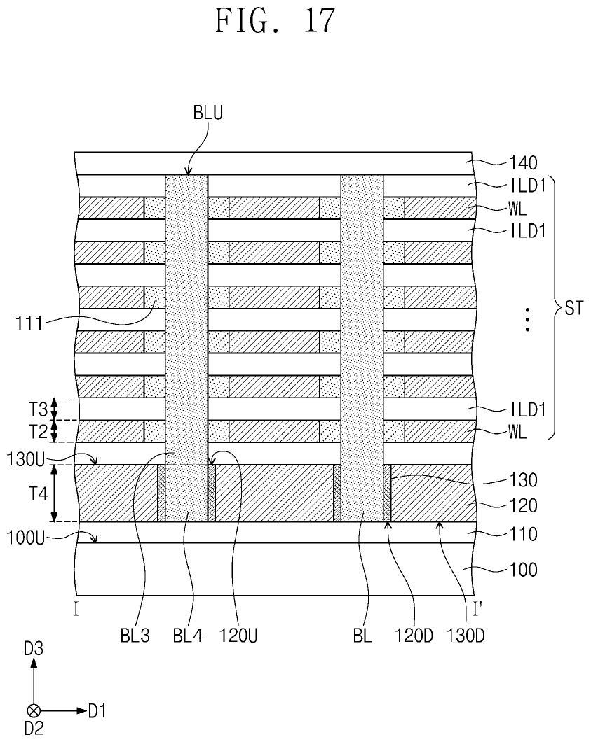

FIG. 17 is a cross-sectional view illustrating a three-dimensional memory device according to some embodiments of the inventive concepts. Hereinafter, differences between the present embodiments and the above embodiments will be mainly described for the purpose of ease and convenience in explanation.

Referring to FIG. 17, a base insulating layer 110 may be disposed on a substrate 100, and an outer electrode 130 may be disposed on the base insulating layer 110. A stack structure ST including first interlayer insulating layers ILD1 and word lines WL which are alternately stacked may be disposed on the outer electrode 130.

Bit lines BL may penetrate the stack structure ST and the outer electrode 130 and may be spaced apart from each other in the first direction D1. Each of the bit lines BL may include a third portion BL3 penetrating the stack structure ST, and a fourth portion BL4 penetrating the outer electrode 130. A fourth thickness T4 of the fourth portion BL4 of the bit line BL in the third direction D3 may be greater than a second thickness T2 of the word line WL in the third direction D3 and a third thickness T3 of the first interlayer insulating layer ILD1 in the third direction D3. Thus, a parasitic capacitance of the bit line BL, which will be described below, may have a sufficiently great value, and an operating speed and reliability of the three-dimensional memory device may be improved.

Dielectric layers 120 may be disposed between the outer electrode 130 and the bit lines BL, respectively, and may surround in plan view side surfaces of the fourth portions BL4 of the bit lines BL, respectively. Top surfaces 120U of the dielectric layers 120 may be substantially coplanar with a top surface 130U of the outer electrode 130, and bottom surfaces 120D of the dielectric layers 120 may be substantially coplanar with a bottom surface 130D of the outer electrode 130. The dielectric layer 120 may be disposed between the outer electrode 130 and the fourth portion BL4 of the bit line BL to form a capacitor including the dielectric layer 120, the outer electrode 130 and the fourth portion BL4 of the bit line BL, and imbalance of a capacitance between the bit line BL and the word line WL may be reduced using a capacitance of the capacitor and a parasitic capacitance between the word lines WL. As a result, the operating speed and reliability of the three-dimensional memory device may be improved.

Storage patterns 111 may be disposed between each of the word lines WL and each of the bit lines BL. The storage patterns 111 may have a shape surrounding a side surface of the bit line BL when viewed in a plan view.

An upper insulating layer 140 may be disposed on the stack structure ST and may cover or overlap top surfaces BLU of the bit lines BL.

The three-dimensional memory device according to the inventive concepts may reduce the imbalance of the parasitic capacitance between the word line and the bit line, and thus a resistive memory device with improved electrical characteristics and reliability may be provided.

While the embodiments of the inventive concepts have been particularly shown and described, it will be understood by one of ordinary skill in the art that variations in form and detail may be made therein without departing from the spirit and scope of the attached claims.

1. A three-dimensional memory device comprising:
a base insulating layer on a substrate;
a stack structure comprising word lines and first interlayer insulating layers which are alternately stacked on the base insulating layer, and a second interlayer insulating layer on an uppermost one of the word lines;
bit lines that are in the stack structure and are spaced apart from each other in a first direction parallel to a top surface of the substrate, wherein ones of the bit lines include respective first portions that protrude from a top surface of the stack structure and respective second portions that are in the stack structure;
an outer electrode on the stack structure and on the first portion of the ones of the bit lines; and
a dielectric layer between the outer electrode and the first portions of the ones of the bit lines, wherein the dielectric layer surrounds side surfaces of the first portions of the ones of the bit lines in plan view,
wherein the outer electrode is spaced apart from the first portions of the ones of the bit lines with the dielectric layer interposed therebetween.

2. The three-dimensional memory device of claim 1, further comprising:
an upper insulating layer on top surfaces of the bit lines, a top surface of the dielectric layer, and a top surface of the outer electrode.

3. The three-dimensional memory device of claim 1, wherein the outer electrode is on top surfaces of the bit lines, and
wherein the dielectric layer extends between the outer electrode and the top surfaces of the bit lines.

4. The three-dimensional memory device of claim 3, wherein the dielectric layer extends between the top surface of the stack structure and the outer electrode.

5. The three-dimensional memory device of claim 1, wherein a first thickness of one of the first portions of the bit lines in a third direction perpendicular to the top surface of the substrate is greater than a second thickness of one of the word lines in the third direction and a third thickness of one of the first interlayer insulating layers in the third direction.

6. The three-dimensional memory device of claim 1, wherein the stack structure further comprises:
storage patterns spaced apart from each other in a third direction perpendicular to the top surface of the substrate,
wherein the storage patterns are between a first one of the bit lines and respective ones of the word lines.

7. The three-dimensional memory device of claim 6, wherein the storage patterns are on a side surface of one of the bit lines in plan view.

8. The three-dimensional memory device of claim 6, wherein ones of the word lines are electrically connected to respective ones of the storage patterns.

9. The three-dimensional memory device of claim 6, wherein the storage patterns include at least one of selenium (Se), tellurium (Te), arsenic (As), antimony (Sb), carbon (C), germanium (Ge), silicon (Si), or indium (In).

10. The three-dimensional memory device of claim 1, wherein the dielectric layer includes at least one of HfO, AlO, TiO, ZrO, or TaO.

11. [symbol]
a base insulating layer on a substrate;
an outer electrode on the base insulating layer;
a stack structure comprising first interlayer insulating layers and word lines which are alternately stacked on the outer electrode;
bit lines that are in the stack structure and the outer electrode and are spaced apart from each other in a first direction parallel to a top surface of the substrate; and
a dielectric layer between ones of the bit lines and the outer electrode and on side surfaces of the ones of the bit lines.

12. The three-dimensional memory device of claim 11, wherein the ones of the bit lines respectively include third portions that are in the stack structure and fourth portions that are in the outer electrode, and
wherein a fourth thickness of the fourth portion of one of the bit lines in a third direction perpendicular to the top surface of the substrate is greater than a second thickness of one of the word lines in the third direction and a third thickness of one of the first interlayer insulating layers in the third direction.

13. The three-dimensional memory device of claim 11, wherein the stack structure further comprises:
storage patterns spaced apart from each other in a third direction perpendicular to the top surface of the substrate,
wherein the storage patterns are between respective ones of the bit lines and respective ones of the word lines.

14. The three-dimensional memory device of claim 13, wherein the storage patterns are on respective side surfaces of the ones of the bit lines.

15. The three-dimensional memory device of claim 13, wherein the storage patterns include at least one of selenium (Se), tellurium (Te), arsenic (As), antimony (Sb), carbon (C), germanium (Ge), silicon (Si), or indium (In).

16. The three-dimensional memory device of claim 11, wherein the dielectric layer includes at least one of HfO, AlO, TiO, ZrO, or TaO.

17-20. (canceled)

21. A three-dimensional memory device comprising:
a base insulating layer on a substrate;
word lines and interlayer insulating layers which are alternately stacked on the base insulating layer;
bit lines that are in the word lines and the interlayer insulating layers, and are spaced apart from each other in a first direction parallel to a top surface of the substrate, wherein the bit lines each includes a first portion that protrudes from a top surface of an uppermost one of the interlayer insulating layers and a second portion that is in the word lines and the interlayer insulating layers;
a dielectric layer on side surfaces of the respective first portions of ones of the bit lines;
an outer electrode on the dielectric layer; and
an upper insulating layer on top surfaces of the bit lines, a top surface of the dielectric layer, and a top surface of the outer electrode.

22. The three-dimensional memory device of claim 21, wherein the top surfaces of the bit lines directly contact a bottom surface of the upper insulating layer.

23. The three-dimensional memory device of claim 21, wherein a top surface of the dielectric layer directly contacts a bottom surface of the upper insulating layer.

24. The three-dimensional memory device of claim 21, wherein a bottom surface of the dielectric layer directly contacts the uppermost one of the interlayer insulating layers.
